(19) United States
(12) Patent Application Publication
(10) Pub. No.: US 2011/0017259 A1
(43) Pub. Date: Jan. 27, 2011

(54) Manually Positionable Solar Tracking System

(75) Inventor: Jeffrey Mann, Cleveland, OH (US)

Correspondence Address: PATENT, COPYRIGHT & TRADEMARK LAW GROUP, 4199 Kinross Lakes Parkway, Suite 275, RICHFIELD, OH, 44286, US

(73) Assignee: Sunflower Solutions, LLC, an Ohio Limited Liability Company

(21) Appl. No.: 12/772,347

(22) Filed: May 3, 2010

Related U.S. Application Data
(60) Provisional application No. 61/175,074, filed on May 4, 2009.

(51) Int. Cl. F16M 11/10; H01L 31/042; F16M 11/26

(52) U.S. Cl. 136/244; 248/122.1

(57) ABSTRACT

Presented herein is a method for manually tracking solar panels using only three orientations (morning, noontime, and afternoon). In this method, panels are manually reoriented at two times during the day to achieve a total of three orientations (more orientations can be used, but have been found to be unnecessary for most applications). A manual solar array tracking system encompassing this method would include a mechanical implementation such that when a user reorients a panel to one of the three positions, it snaps, or is similarly easily guided and latched into position. Such a system would also have a mechanical setting that would be changed several times a year, most likely on a monthly schedule. This setting would adjust the daily panel orientation settings to account for the changing sun position at that time of year.

### RELATED APPLICATIONS

The present application claims benefit of U.S. Provisional Application Ser. No. 61/175,074, filed on May 4, 2009 and incorporated by reference herein as if fully rewritten.

### BACKGROUND OF THE INVENTION

1. Technical Field of the Invention

The present invention generally relates to methods and devices for allowing solar panels to track the movement of the sun and, more particularly, to a three positions manual solar tracking system for optimizing a balance been installation cost and operational efficiency.

2. Description of the Background Art

Solar panels, i.e. arrays of photovoltaic cells arranged in panels, are in increasing use today. The use of such photo voltaic cells is expected to accelerate as the cost of the cells decreases.

Various forms of solar trackers are also well known, for use with arrays or panels of photovoltaic cells. However, the most efficient trackers, for absorbing maximum sunlight in a given day, have been multiple-axis trackers, which rotate about more than one axis so as to follow both the azimuth variation (progression of the sun's bearing angle, i.e. east to south to west), and the sun's change in elevation angle from the horizon.

The problem presented by using automated tracking systems is twofold: First, there is a significant cost in adding such a system to a solar array. In many cases, this cost is approximately equal to adding additional solar panels to achieve the same daily energy output. Second, as a complex computer-controlled system with many moving parts, automated tracking adds additional points of failure. As a complex electric and mechanical system, it requires certain skills to maintain and fix. While an automated tracking system is still appropriate for permanent and large scale installations in the developed world, the cost and complexity prevent it from working in portable systems and small systems in developing counties.

A search of the prior art did not disclose any patents that read directly on the claims of the instant invention; however, the following references were considered related.

U.S. Pat. No. 6,284,968, issued in the name of Niesyn, discloses a solar-tracking system for changing the orientation of a solar-dependent system, such as solar heating apparatuses, solar-generators, solar concentrators, telescopes, and the like. This reference teaches the use of an orbital gear linkage that can track at a constant velocity of 366.25 revolutions clockwise per year. Such a system, while incorporating accuracy, further incorporates complexity and its associated costs and other drawbacks.

U.S. Pat. No. 6,239,353, issued in the name of Hal et al., discloses a solar tracker that teaches the use of a single axis operation that simulates a dual-axis tracking. However, again the use of motors to automate the tracking of the system incorporates cost and complexity that would prevent it from working in portable systems and small systems in developing counties.

U.S. Pat. No. 6,960,717, issued in the name of Stuart et al, discloses an adjustable solar panel that teaches a non-rotational, motor driven position adjustment. Such a device is anticipated as being tilt-able for use in positioning signage for optimal orientation to the viewer.

The approaches described in this section could be pursued, but are not necessarily approaches that have been previously conceived or pursued. Therefore, unless otherwise indicated herein, the approaches described in this section are not prior art to the claims in this application and are not admitted to be prior art by inclusion in this section.

### SUMMARY OF THE INVENTION

### 1. Technical Problem

It is therefore an object of the present invention to provide an improved mechanism for providing sufficient solar tracking to allow for a reasonably useful result, all at a minimum of initial cost and easy of ongoing operation.

### 2. Solution to Problem

The angle of incident light on a solar panel is the key limiting factor that prevents an array of solar panels from achieving maximum use of available sunlight. The fractional power of available sunlight on a solar panel is calculated as the cosine of the angle of incident. While a solar array system that tracks the sun in order to keep this angle close to 0 achieves nearly 100% solar efficiency, a system with fixed orientation achieves 100% only at high noon and efficiency falls quickly during the outer thirds of sunlight time.

Various forms of solar trackers are also well known, for use with arrays or panels of photovoltaic cells. However, the most efficient trackers, for absorbing maximum sunlight in a given day, have been multiple-axis trackers, which rotate about more than one axis so as to follow both the azimuth variation (progression of the sun's bearing angle, i.e. east to south to west), and the sun's change in elevation angle from the horizon.

It is a feature of the present invention to provide an improved solution for manually tracking a solar array using only three angle settings per day. These settings correspond to a morning, noontime, and afternoon setting for solar panel angles. It has been found that such a increases the daily energy output of a solar array when compared to stationary systems by typical increase of 50% to 100%. Under most typical circumstances, the array solar efficiency exceeds 90% for three fourths or more of the daylight time. This method dramatically reduces the cost, weight, and complexity of tracking equipment while remaining within an estimated 15% of the solar efficiency of an automated continuous tracking system.

### 3. Advantageous Effects of Invention

Referring now to FIG. 1, the movement of the sun across the sky is shown on Apr. 20, 2008 at 20N, 80E. The dark blue line is the movement of the sun from east to west. When a single fixed orientation of solar panel is used, the efficiency represented by the brown line results. When three orientations are used, the efficiency is enhanced and is shown with the pink line. The three panel orientations are plotted using red circles (representing the angle perpendicular to the plane of the panels). In a fixed orientation system, only the center orientation would be used (this is the noon-time orientation).

FIG. 2 shows a graph of the efficiency of the solar panels over time. As can be more clearly seen is this time plot, the time the solar panels achieve 90% or greater efficiency is greatly increased by adding a morning and afternoon orientation.

In accordance with the preferred embodiment the present invention a low cost, manually operated system for tracking solar panels is provided that is low cost in its initial and operational cost, easy to maintain, and yet still allows for an operational efficiency of 90% or greater as compared to much more complicated and expensive arrangements.

### BRIEF DESCRIPTION OF THE DRAWINGS

The advantages and features of the present invention will become better understood with reference to the following more detailed description and claims taken in conjunction with the accompanying drawings, in which like elements are identified with like symbols, and in which:

FIG. 1 is a graph depicting the movement of the sun across the sky is shown on Apr. 20, 2008 at 20N, 80E.;

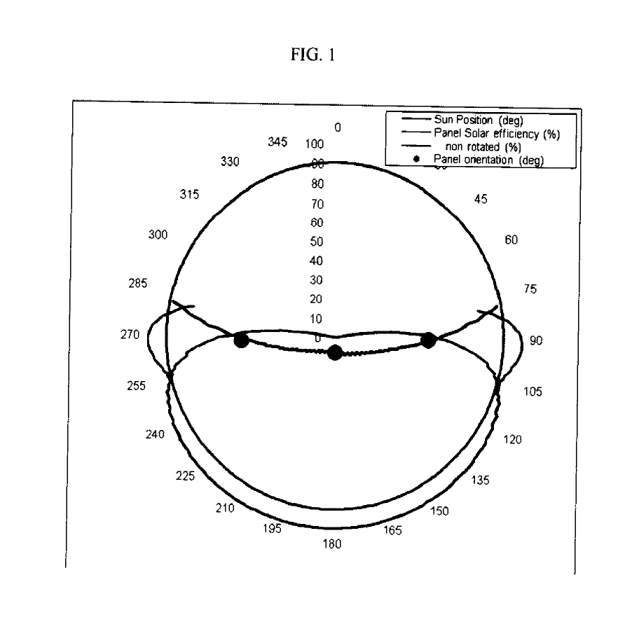

FIG. 2 is a graph of the efficiency over time for a three-position manual solar tracking system according to the preferred embodiment of the present invention;

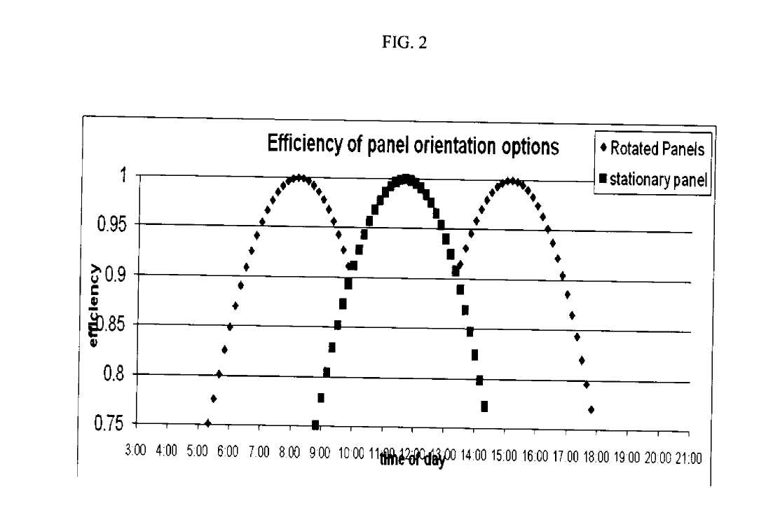

FIG. 3 is a perspective view of a three-position manual solar tracking system according to the preferred embodiment of the present invention;

FIG. 4 is a front elevational view thereof;

FIG. 5 is a side elevational view thereof;

FIG. 6 is an exploded perspective thereof;

FIG. 7 is a perspective view of a three-position manual solar tracking system according to a first alternate embodiment of the present invention;

FIG. 8 is a front elevational view thereof;

FIG. 9 is a top plan view thereof;

FIG. 10 is a perspective view of a vertical support shaft for use therewith;

FIG. 11 is a perspective view of a horizontal support shaft for use therewith;

FIG. 12 is a perspective view of a set screw shaft collar for use therewith; and

FIG. 13 and FIG. 14 are photographs of an operational prototype of a three-position manual solar tracking system according to the first alternate embodiment.

### DESCRIPTION OF THE PREFERRED EMBODIMENTS

The best mode for carrying out the invention is presented in terms of its preferred embodiment, herein depicted within the Figures.

### 1. Detailed Description of the Figures

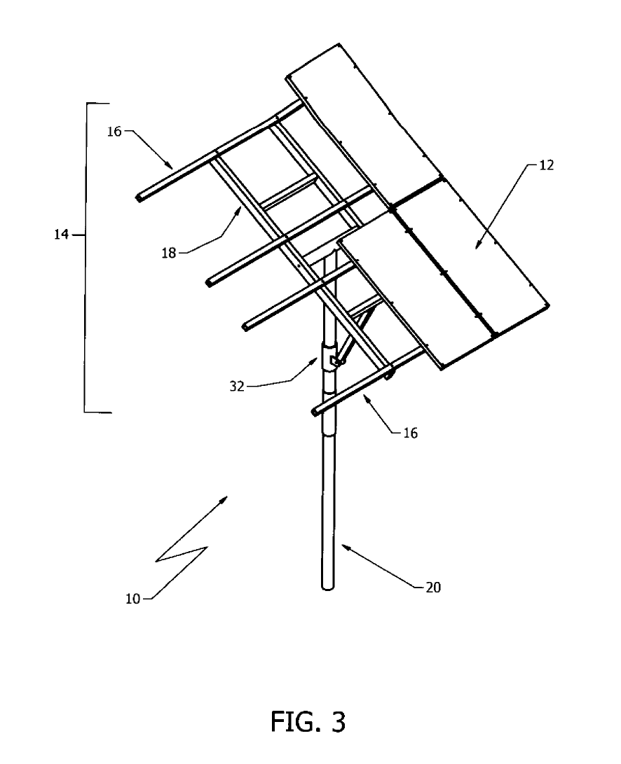

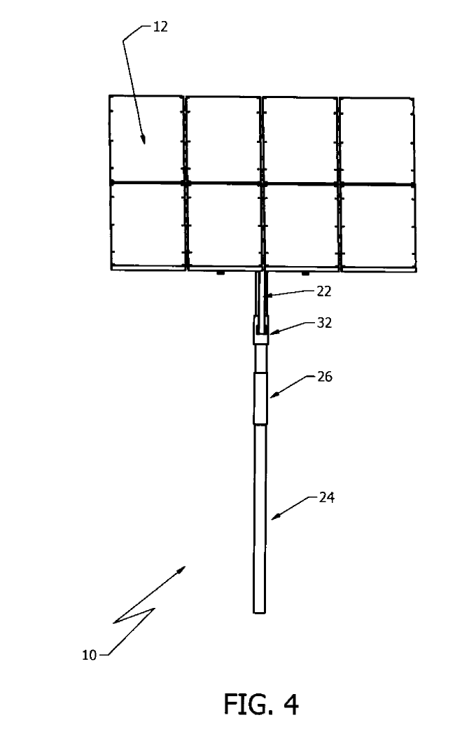

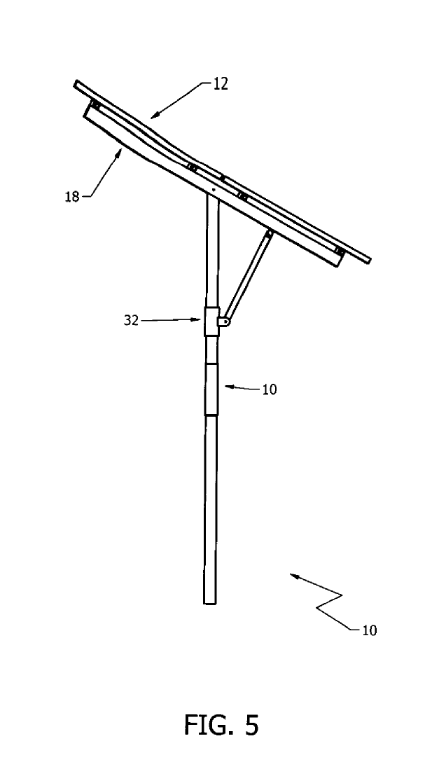

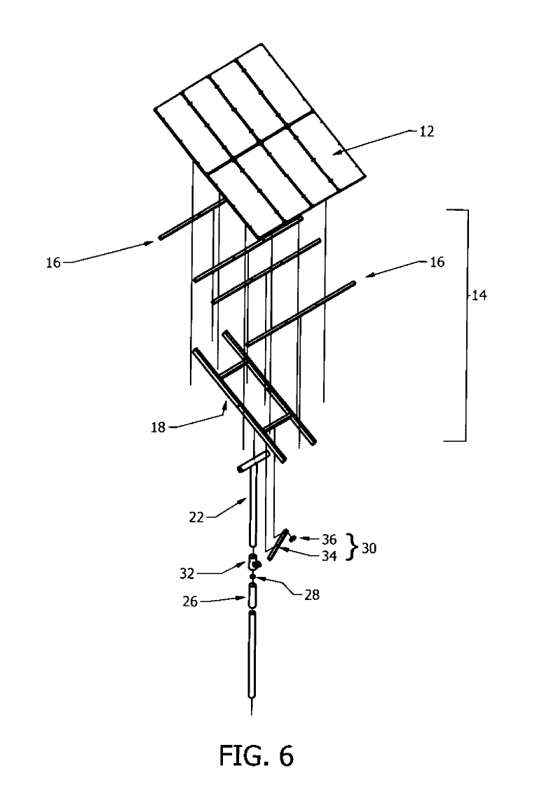

Referring now to FIG. 3-6, a three-position manual solar tracking system 10 is shown according to the preferred embodiment of the present invention. Such a system 10 allows for use with a method for manually tracking solar panels 12 using only three orientations (morning, noontime, and afternoon). The solar tracking panel 12 are affixed to a solar panel support 14 in which a plurality of cross supports 16 are connected to the back side of the solar panels 12 and an axial support bracket 18 thereafter affixes to the cross supports 16 to thereby form an overall planar assembly. The assembled solar panels 12 and solar panel support 14 is pivotally affixed to a supporting pole 20. The supporting pole 20 I anticipated as being formed of an upper pole element 22 affixed onto a lower pole element 24, although other configurations can be envisioned. The upper pole element 22 terminates at its upper end in a generally T-shaped mount, and along its linear shaft supports a zenith axial support 30 formed of a zenith collar 32 that is slidingly aligned along the pole shaft, and pivotally connects to a zenith arm 34 that is connected on its distal end to a zenith axial support hinge 36 that is in mechanical communication with the solar panel support 14, and shown herein as being in mechanical communication with the cross support 16.

As would be obvious to a person having ordinary skill in the relevant art, having subsequently be exposed to the present teachings, a three-position manual solar tracking system 10 of the present exemplary embodiment can rotated about an azimuth pivot 28 in which the upper supporting pole 22 rests on a ball plate 28 and is rotatably about the lower support pole 24. Further, the zenith axial support 30, when positioned higher or lower about the supporting pole 20, angles the solar panel support 14 accordingly. In this method, panels 12 are manually reoriented at two times during the day to achieve a total of three orientations. As would be obvious to one having ordinary skill in the relevant art, in light of the present teachings, it would be found that a limited number of additional orientations can be used, but would have minimal additional have been found to be unnecessary for most applications). The manual solar array tracking system 10 encompassing this method would include a mechanical implementation such that when a user reorients a panel to one of the three positions, it snaps, or is similarly easily guided and latched into position. Such a system 10 would also have a mechanical setting that would be changed several times a year, most likely on a monthly schedule. This setting would adjust the daily panel orientation settings to account for the changing sun position at that time of year.

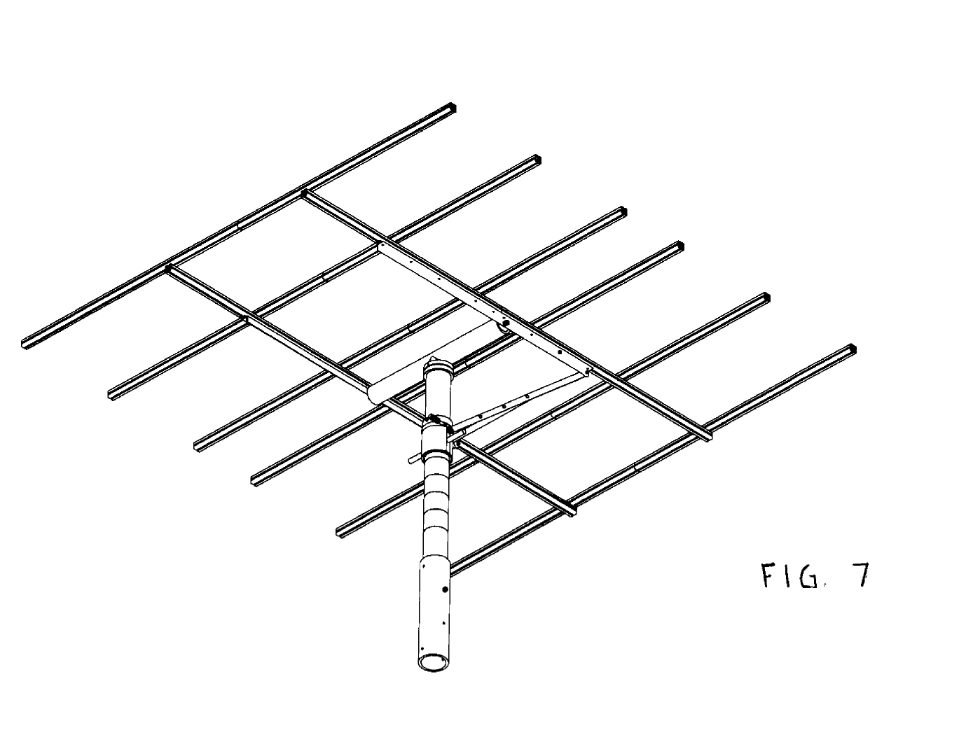

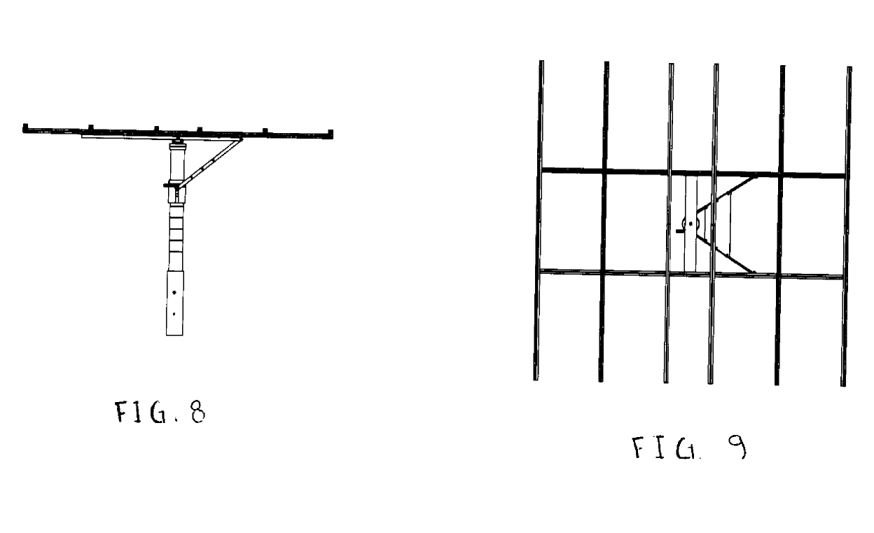

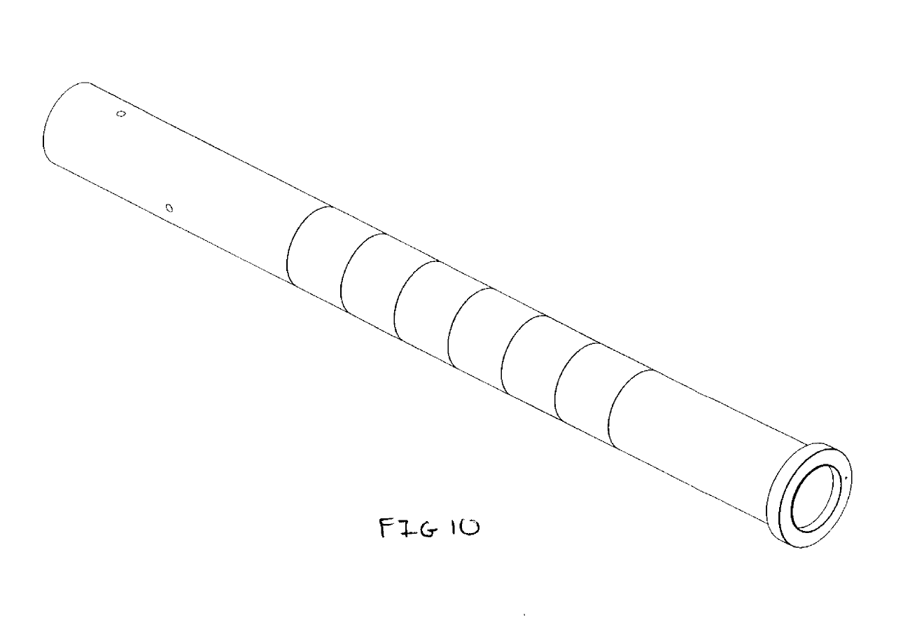

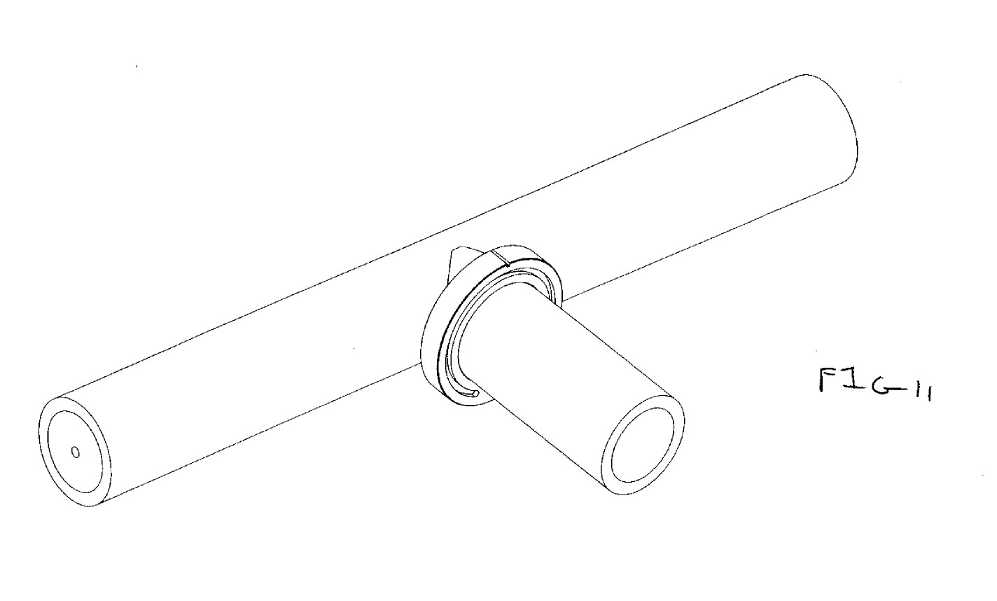

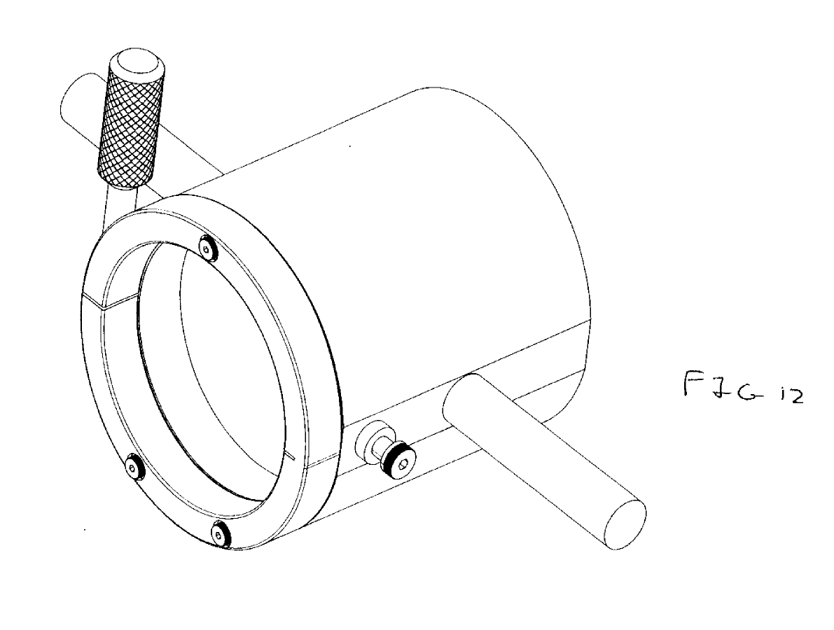

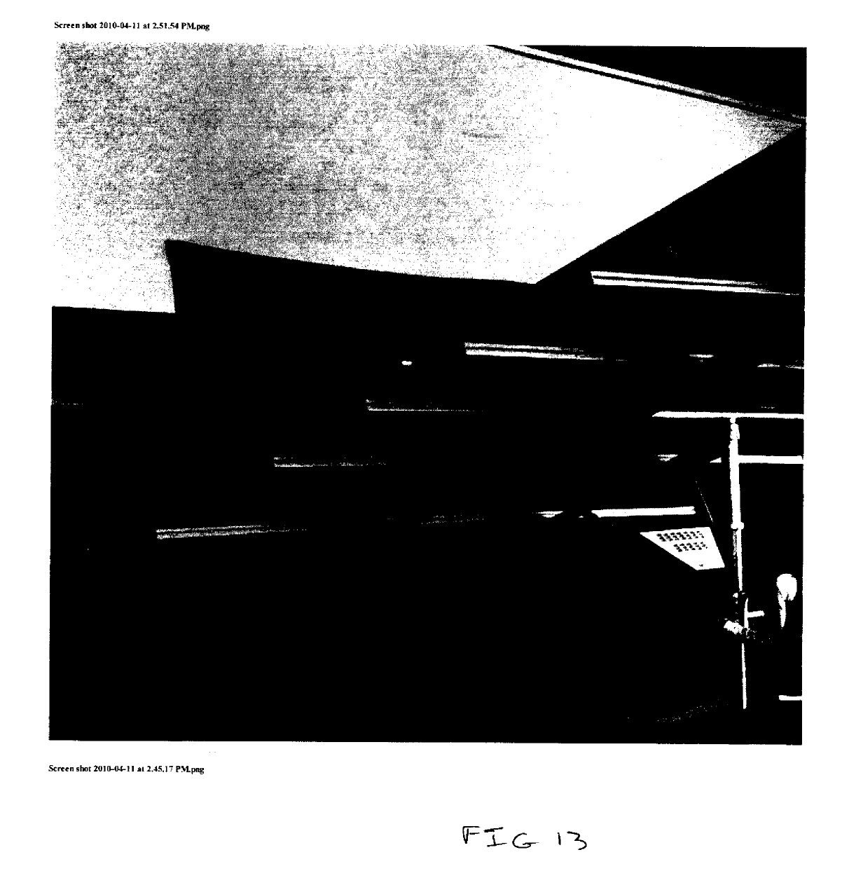

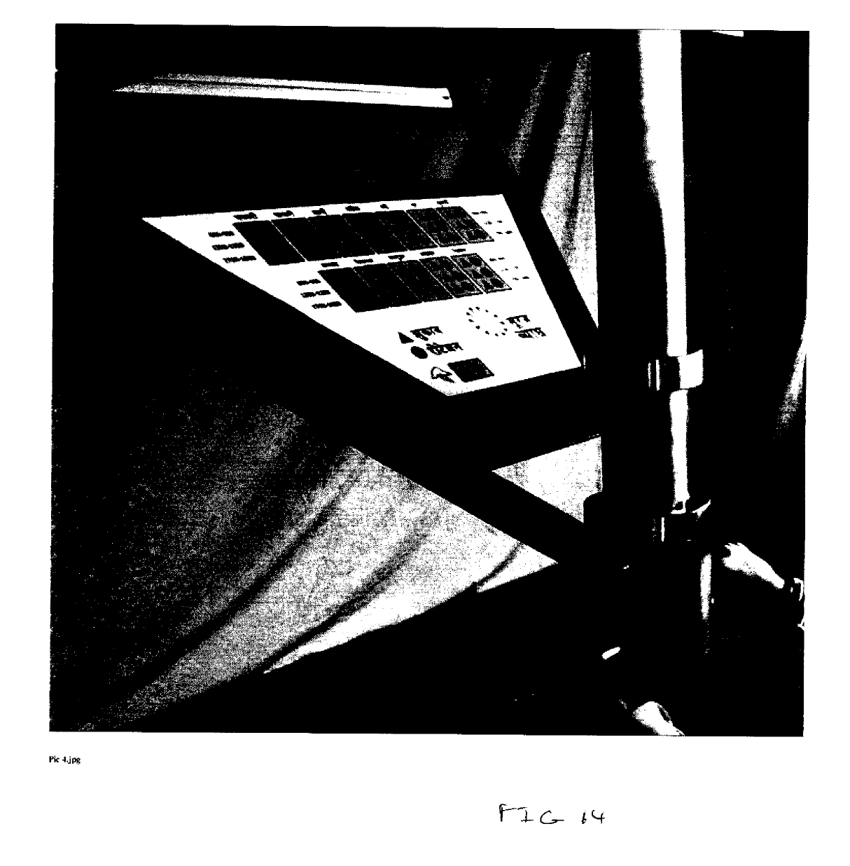

Referring now to FIG. 7-14, the three-position manual solar tracking 10 is shown according to a first alternate embodiment of the present invention. Such a system provides the identical use of manually tracking solar panels using only three orientations (morning, noontime, and afternoon), but incorporates a slightly different mounting and locking mechanisms. Such an alternate embodiment is shown and described by was of disclosing the best modes of the present invention as known at the time of filing of this application. As was found while developing the operational prototype as best shown in FIG. 13-14, the alteration of the vertical support shaft, horizontal support shaft, set screw shaft collar, and other elements can accommodate changes is configuration that would be considered by a person having ordinary skill in the relevant art as being merely a design choice having functional equivalents in light of the intended scope and function as shown and described broadly within this specification. As a result, it is intended that such other design modifications should be considered wholly equivalent with the present invention and within the intended functionality.

### 2. Operation of the Preferred Embodiment

It is envisioned that a manual tracking system encompassing the three-position manual tracking method presented herein provides a way to easily slide, shift, or reposition the solar panel array into each of the three positions. Such an implementation would be designed so that the user would simply grab the array and gently rotate until the array sticks into the now position. With only three positions to choose from, the act of reorienting the array would consist of simply grabbing the panels and moving into the next position to which it sticks. Typically a window of 30 minutes to one hour exists to rotate the panels into the next position without significantly affecting the efficiency of the system.

Over the course of the year, the sun's position in the sky changes significantly. So, the three daily orientations will need to be changed to match the sun's position in the sky. It is expected that this will be done a monthly basis by changing one pin on the tracking apparatus to engage new angles that will be used for the given month.

In order to find the angles require for the solar panel array, several decisions must be made. First, an angle at which the sun exceeds the horizon must be picked for assuming all obstacles (such as trees and building) have been cleared. For the examples in this paper, an angle of 15 degrees over the horizon has been chosen as the angle at which the sun becomes useful.

Next the time at which the 15 degree angle is exceeded in the morning is calculated, and the angle the sun falls below this angle in the evening is also calculated. These will be the time the sun is first assumed useful and the time the sun is last assumed useful. This block of time is then divided into thirds. The three angles chosen for the solar panel arrays correspond to the angles of the sun at the midpoint of each of these three time segments. (The midpoint of the middle segment corresponds to high noon.)

The foregoing descriptions of specific embodiments of the present invention have been presented for purposes of illustration and description. They are not intended to be exhaustive or to limit the invention to the precise forms disclosed, and obviously many modifications and variations are possible in light of the above teaching. The embodiments were chosen and described in order to best explain the principles of the invention and its practical application, to thereby enable others skilled in the art to best utilize the invention and various embodiments with various modifications as are suited to the particular use contemplated. It is intended that the scope of the invention be defined by the Claims appended hereto and their equivalents. Therefore, the scope of the invention is to be limited only by the following claims.

1. A manual solar tracking system comprising at least one solar panel affixed to a solar panel support: said solar panel support comprising a plurality of cross supports connected to a back side of said solar panels and an axial support bracket affixes to the cross supports to thereby form an overall planar assembly and a supporting pole pivotally affixed to said solar panel support: wherein said system is adapted for use with and allows a method for manually tracking solar panels using only three orientations corresponding to morning, noontime, and afternoon.

2. The manual solar tracking system of claim 1, wherein said supporting comprises of an upper pole element affixed onto a lower pole element, said upper pole element terminating at its upper end in a generally T shaped mount, and along its linear shalt.

3. The manual solar tracking system of claim 2, further comprising a zenith axial support formed of a zenith collar that is slidingly aligned along said pole shaft, and pivotally connected to a zenith arm that is connected on its distal end to a zenith axial support hinge that is in mechanical communication with the solar panel support.

4. The manual solar tracking system of claim 3, wherein said supporting pole is pivotally affixed to said solar panel about an azimuth pivot in which the upper supporting pole rests on a ball plate and is rotatably about the lower support pole; wherein when said zenith axial support, when positioned higher or lower about the supporting pole, angles the solar panel support respectively.

5. A method of manually positioning said solar tracking system of claim 4, said method comprising:
a. Selecting one of at least three positions to reorient the array within 30 minutes to one hour of a target time;
b. Repeating step a two additional times throughout the day.

6. The method of claim 5, further comprising adjusting said three daily orientations to match the sun's position in the sky on a monthly basis by changing one pin on the tracking apparatus to engage new angles that will be used for the given month.

7. The method of claim 6, wherein said angles arc at locations which the sun exceeds the horizon and free of all obstacles.

8. The method of claim 6, wherein said angles comprise: a first angle when the sun is 15 degrees over the morning horizon; a midpoint of the middle segment corresponds to high noon; and a final point when the sun is 15 degrees before the evening horizon.

9. A solar tracking system comprising:
a solar panel support for supporting at least one otherwise conventional solar panel;
said solar panel support being pivotally affixed to a supporting pole and operatively connected to a zenith axial support formed of a zenith collar that is slidingly aligned along a pole shaft, and pivotally connects to a zenith arm that is connected on its distal end to a zenith axial support hinge that is in mechanical communication with the solar panel support such as to be manually positioned between a first position and a second position;
said pole shaft further being adapted to rotated about an azimuth;
wherein said solar tracking system is operatively configured for being manually reoriented at two times during the day to achieve a total of three orientations.

10. The solar tracking system of claim 9, further comprising a mechanical adjustment capable of being changed several times a year to adjust the daily panel orientation settings to account for the changing sun position at that time of year.

11. The solar tracking system of claim 10, wherein said several times a year to comprises once a month.

12. The solar tracking system of claim 9, wherein said manual reorientation at two times during the day to achieve a total of three orientations is selected from of at least three positions to reorient the array within 30 minutes to one hour of a target time.

13. The solar tracking system of claim 9, wherein: said first position is at a first angle when the sun is 15 degrees over the morning horizon.

14. The solar tracking system of claim 13, wherein said second position is at a midpoint that corresponds to high noon.

15. The solar tracing system of claim 14, wherein said third position is at a final point when the sun is 15 degrees before the evening horizon.
